(19) United States
(12) Patent Application Publication
(10) Pub. No.: US 2024/0404943 A1
(43) Pub. Date: Dec. 5, 2024

(54) INTEGRATED CIRCUIT DEVICES WITH FISHBONE CAPACITOR STRUCTURES

(71) Applicant: Intel Corporation, Santa Clara, CA (US)

(72) Inventor: Denzil Frost, Rio Rancho, NM, ID (US)

(73) Assignee: Intel Corporation, Santa Clara, CA (US)

(21) Appl. No.: 18/327,968

(22) Filed: Jun. 2, 2023

(51) Int. Cl. H01L 23/522

(52) U.S. Cl. CPC H01L 23/5223; H01L 28/86; H01L 28/90

(57) ABSTRACT

Disclosed herein are IC devices with fishbone capacitor structures. An example capacitor structure includes a first capacitor electrode, a second capacitor electrode, and a third capacitor electrode, wherein the first capacitor electrode is a first line with protrusions on a side of the first line, the second capacitor electrode is a second line with protrusions on a first side of the second line and protrusions on a second side of the second line, the third capacitor electrode is a third line with protrusions on a side of the third line, the protrusions on the side of the first line and the protrusions on the first side of the second line form a first interdigitated capacitor structure, and the protrusions on the side of the third line and the protrusions on the second side of the second line form a second interdigitated capacitor structure.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component and each interconnect becomes increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a schematic illustration of a cross-sectional view of an example integrated circuit (IC) device in which one or more fishbone capacitor structures may be implemented, according to some embodiments of the present disclosure.

FIG. 2 is a cross-sectional side view of an example IC device that may include one or more fishbone capacitor structures in accordance with any of the embodiments disclosed herein.

FIGS. 3A and 3B illustrate top-down views of example fishbone capacitor structures, according to some embodiments of the present disclosure.

FIGS. 4A and 4B are top views of a wafer and dies that include one or more fishbone capacitor structures in accordance with any of the embodiments disclosed herein.

FIG. 5 is a cross-sectional side view of an IC device assembly that may include one or more fishbone capacitor structures in accordance with any of the embodiments disclosed herein.

FIG. 6 is a block diagram of an example computing device that may include one or more fishbone capacitor structures in accordance with any of the embodiments disclosed herein.

### DETAILED DESCRIPTION

Disclosed herein are IC devices with fishbone capacitor structures. An example capacitor structure includes a first capacitor electrode, a second capacitor electrode, and a third capacitor electrode, wherein the first capacitor electrode is a first line with protrusions on a side of the first line, the second capacitor electrode is a second line with protrusions on a first side of the second line and protrusions on a second side of the second line, the third capacitor electrode is a third line with protrusions on a side of the third line, the protrusions on the side of the first line and the protrusions on the first side of the second line form a first interdigitated capacitor structure, and the protrusions on the side of the third line and the protrusions on the second side of the second line form a second interdigitated capacitor structure.

In some implementations, fishbone capacitor structures described herein may be used as decoupling capacitors. A decoupling capacitor is a capacitor used to decouple one part of an electrical network from another. Noise caused by other circuit elements can be shunted through the decoupling capacitor, reducing the effect it has on the rest of the circuit.

Decoupling capacitors are typically included in semiconductor packages in order to lower the inductance through the package by reducing the lead length. Decoupling capacitors placed close to power consuming circuits are able to smooth out voltage variation with charges stored on them. The stored charge either dissipates or is used as a local power supply to device inputs during signal switching stages, allowing the decoupling capacitors to negate the effects of voltage noise induced into the system by parasitic inductance. Off-chip decoupling capacitors, however, are not sufficient for very high speed microprocessor applications. Since the decoupling capacitors are located at a relatively long distance from the switching circuits, the time delay caused by the long inductance path makes the off-chip capacitors unusable with gigahertz switching circuits.

In order to sustain high frequency circuit operation, an ample amount of capacitive decoupling must be provided close to the switching circuits. Although it is possible to integrate chip capacitors within the active circuitry of an IC device, the capacitors compete for valuable die area that could be used for building additional circuits. Due to the limited area in which to build these capacitors, the overall capacitive decoupling that they provide is also limited.

One advantage of fishbone capacitor structures described herein is that they may be moved to the back end of line (BEOL) layers (also referred to as “backend”) of an advanced complementary metal oxide semiconductor (CMOS) process. In particular, including a fishbone capacitor structure in a metal layer of a metallization stack above a support (e.g., a substrate, a die, a wafer, or a chip) having active circuitry in the front end of line (FEOL) layer and, possibly, in lower BEOL layers may allow realizing decoupling capacitors with sufficient capacitive decoupling close to the active circuitry of an IC device without occupying valuable die area where active circuitry can be built. As such, fishbone capacitor structures described herein may be used to address the scaling challenges of conventional decoupling capacitors and be compatible with advanced CMOS processes.

Furthermore, conventional metal-insulator-metal (MIM) capacitors require at least one patterning step per capacitor electrode because each capacitor electrode needs an independent connection to the power delivery network. Each patterning step increases costs. Fishbone capacitor structures may allow providing MIM capacitors at a reduced cost due to simpler patterning, while maintaining the ability to provide independent connections between capacitor electrodes and the power delivery network. Other technical effects will be evident from various embodiments described here.

Various IC devices with fishbone capacitor structures as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. Although certain elements may be referred to in the singular herein, such elements may include multiple sub-elements. For example, “an insulator material” may include one or more insulator materials. The term “insulating” and variations thereof (e.g., “insulative” or “insulator”) means “electrically insulating,” the term “conducting” and variations thereof (e.g., “conductive” or “conductor”) means “electrically conducting,” unless otherwise specified. For example, the term “insulating material” refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. With reference to optical signals and/or devices, components and elements that operate on or using optical signals, the term “conducting” can also mean “optically conducting.”

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

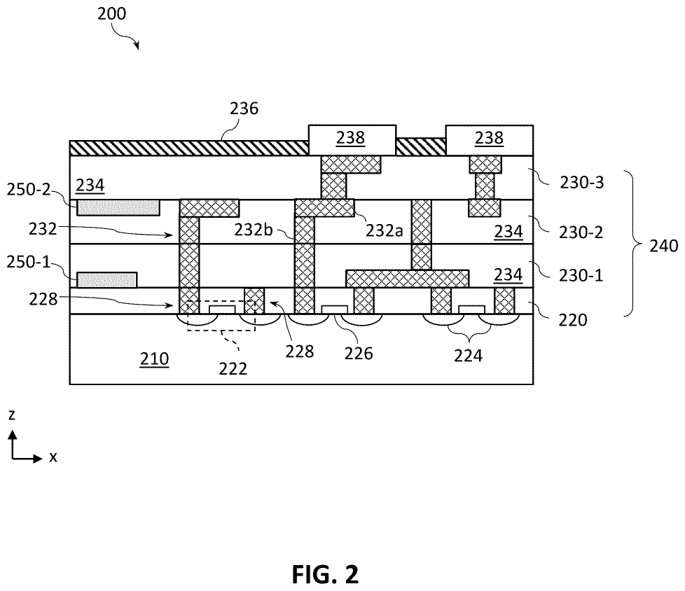

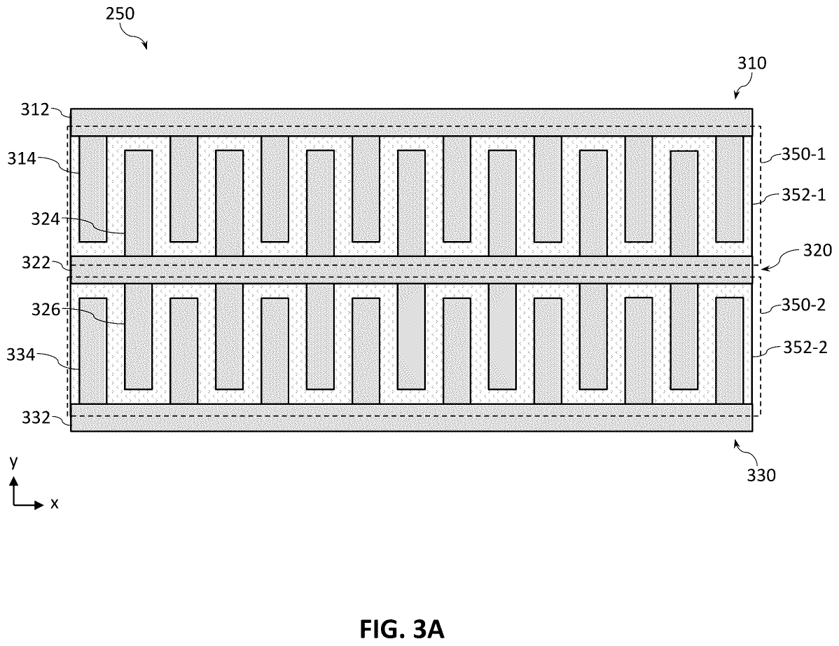

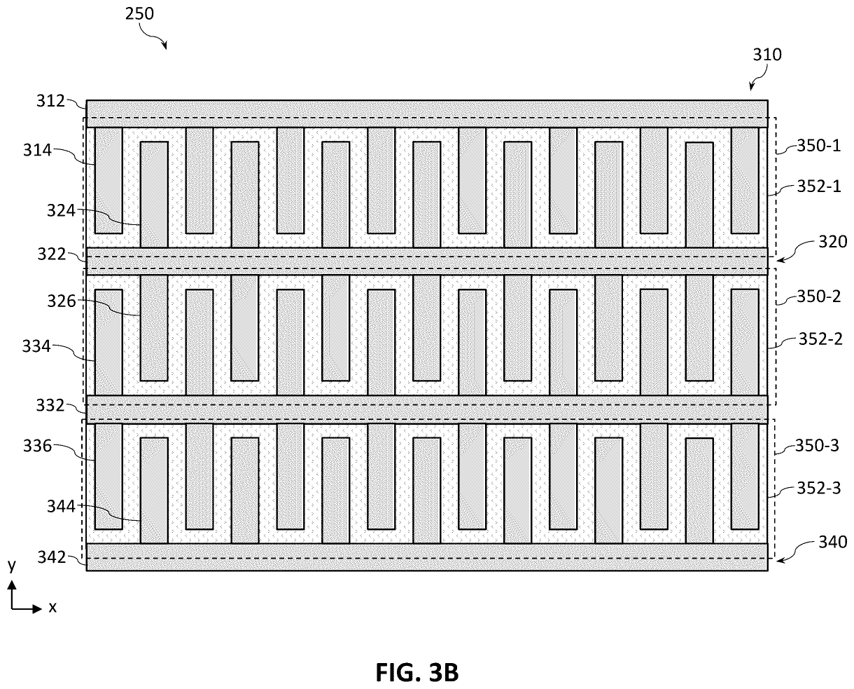

Any of the features discussed with reference to any of accompanying drawings herein may be combined with any other features to form IC devices with fishbone capacitor structures, as appropriate. A number of elements of the drawings are shared with others of the drawings; for ease of discussion, a description of these elements is not repeated, and these elements may take the form of any of the embodiments disclosed herein. If multiple instances of certain elements are illustrated, then, in some cases, to not clutter the drawings only some of these elements may be labeled with a reference sign and other ones of these elements are not labeled (e.g., although FIG. 2 illustrates three transistors 222, only one of them is labeled with a reference sign). However, in other cases, for ease of explanation, different instances of a given element in a single drawing may be referred to with numbers 1, 2, and so on, after a dash (e.g., FIG. 2 illustrates two fishbone capacitor structures 250, labeled individually as a first fishbone capacitor structure 250-1 and a second fishbone capacitor structure 250-2). For convenience, if a collection of drawings designated with different letters are present, e.g., FIGS. 3A-3B, such a collection may be referred to herein without the letters, e.g., as “FIG. 3.”

The drawings are not necessarily to scale. Although many of the drawings illustrate rectilinear structures with flat walls and right-angle corners, this is simply for ease of illustration and may not reflect real-life process limitations which may cause various features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used to describe a range of dimensions, the phrase “between X and Y” represents a range that includes X and Y. When used to describe a location of an element, the phrase “between X and Y” represents a region that is spatially between element X and element Y. The description may use the phrases “in an embodiment” or “in embodiments,” which may each refer to one or more of the same or different embodiments. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−20%, e.g., within +/−5% or within +/−2%, of a target value based on the context of a particular value as described herein or as known in the art.

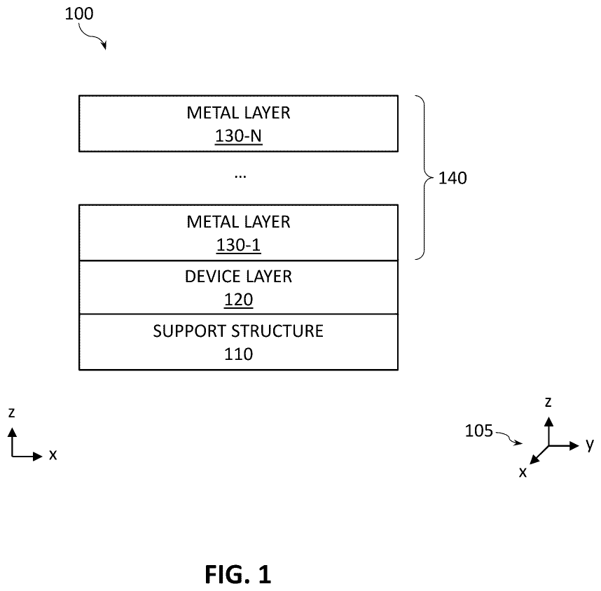

FIG. 1 provides a schematic illustration of a cross-sectional view of an example IC device 100 in which one or more fishbone capacitor structures may be implemented, according to some embodiments of the present disclosure. FIG. 1 illustrates an example coordinate system 105 with axes x-y-z so that the various planes illustrated in FIG. 1 and in some subsequent FIGS. may be described with reference to this coordinate system.

As shown in FIG. 1, in general, the IC device 100 may include a support structure 110, a device layer 120, and a plurality of metal layers 130, labeled as a metal layer 130-1 through metal layer 130-N, where N is an integer greater than 1. Together, the metal layers 130 may be referred to as a metallization stack 140. The illustration of FIG. 1 is intended to provide a general orientation and arrangement of various layers with respect to one another, and, unless specified otherwise in the present disclosure, includes embodiments of the IC device 100 where portions of elements described with respect to one of the layers shown in FIG. 1 may extend into one or more, or be present in, other layers.

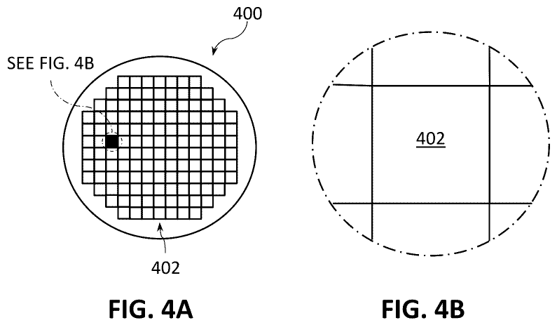

The support structure 110 may be any suitable support over which the device layer 120 and the metallization stack 140 may be provided. For example, the support structure 110 may be a substrate, a die, a wafer or a chip. The support structure 110 may, e.g., be the wafer 400 of FIG. 4A, discussed below, and may be, or be included in, a die, e.g., the singulated die 402 of FIG. 4B, discussed below. The support structure 110 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure 110 may be a printed circuit board (PCB) substrate. Although a few examples of materials from which the substrate may be formed are described here, any material that may serve as a foundation upon which a semiconductor device implementing any of the fishbone capacitor structures as described herein may be built falls within the spirit and scope of the present disclosure.

The device layer 120 may include any combination of active ICs provided over the support structure 110. For example, in some embodiments, the device layer 120 may include various logic layers, circuits, and devices (e.g., logic transistors) to drive and control a logic IC. In some embodiments, the device layer 120 may include memory devices/circuits.

Various layers of the metallization stack 140 may be, or include, metal layers of a BEOL. As used herein, the term “metal layer” may refer to a layer above a support structure 110 that includes electrically conductive interconnect structures (e.g., conductive lines and conductive vias) for providing electrical connectivity between different IC components. Metal layers described herein may also be referred to as “metal layers” to clearly indicate that these layers include electrically conductive interconnect structures which may, but does not have to, be metal. Various metal layers of the metallization stack 140 may be used to interconnect the various inputs and outputs of the active devices (e.g., transistors) in the device layer 120. Generally speaking, each of the metal layers of the metallization stack 140 may include a conductive line (also sometimes referred to as a “trench,” a “trace,” or a “metal line”) and/or a conductive via. Conductive lines of a metal layer are configured for transferring signals and power along electrically conductive (e.g., metal) structures extending in the x-y plane (e.g., in the x or y directions), while the conductive vias of a metal layer are configured for transferring signals and power through electrically conductive structures extending in the z-direction, e.g., to any of the adjacent metal layers above or below. Accordingly, conductive vias connect interconnect structures (e.g., conductive lines and/or conductive vias) of one metal layer to interconnect structures of an adjacent metal layer. While referred to as “metal” layers, various layers of the metallization stack 140 may include only certain patterns of conductive metals, e.g., copper (Cu), aluminum (Al), tungsten (W), or cobalt (Co), or metal alloys, or more generally, patterns of an electrically conductive material, formed in an insulating medium such as an interlayer dielectric (ILD). The insulating medium may include any suitable ILD materials such as silicon oxide, carbon-doped silicon oxide, silicon carbide, silicon nitride, aluminum oxide, and/or silicon oxynitride.

One example implementation of the IC device 100 is shown in FIG. 2. FIG. 2 is a cross-sectional side view of an example IC device 200 that may include one or more fishbone capacitor structures in accordance with any of the embodiments disclosed herein. The IC device 200 is an example of the IC device 100, as explained below.

The IC device 200 may be formed on a substrate 210, where the substrate 210 may be any suitable support structure as described herein, e.g., the support structure 110 of FIG. 1 and/or the wafer 400 of FIG. 4A. The substrate 210 may be part of a singulated die (e.g., the dies 402 of FIG. 4B) or a wafer (e.g., the wafer 400 of FIG. 4A).

The IC device 200 may include one or more device layers 220 disposed on the substrate 210, where, together, the one or more device layers 220 may be an example of the device layer 120 of the IC device 100. The device layer 220 may include features of one or more transistors 222 (e.g., metal-oxide-semiconductor field-effect transistors (MOSFETs)) formed on the substrate 210. The device layer 220 may include, for example, one or more source and/or drain (S/D) regions 224, a gate 226 to control current flow in the transistors 222 between the S/D regions 224, and one or more S/D contacts 228 to route electrical signals to/from the S/D regions 224. The transistors 222 may include additional features not depicted for the sake of clarity, such as device isolation regions, gate contacts, and the like. The transistors 222 are not limited to the type and configuration depicted in FIG. 2 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

The S/D regions 224 may be formed within the substrate 210 adjacent to the gate 226 of each transistor 222, using any suitable processes known in the art. For example, the S/D regions 224 may be formed using either an implantation/diffusion process or a deposition process. In the former process, dopants such as boron, aluminum, antimony, phosphorous, or arsenic may be ion-implanted into the substrate 210 to form the S/D regions 224. An annealing process that activates the dopants and causes them to diffuse farther into the substrate 210 may follow the ion implantation process. In the latter process, an epitaxial deposition process may provide material that is used to fabricate the S/D regions 224. In some implementations, the S/D regions 224 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 224 may be formed using one or more alternate semiconductor materials such as germanium or a group III-V material or alloy. In further embodiments, one or more layers of metal and/or metal alloys may be used to form the S/D regions 224. In some embodiments, an etch process may be performed before the epitaxial deposition to create recesses in the substrate 210 in which the material for the S/D regions 224 is deposited.

Each transistor 222 may include a gate 226 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer. For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 222 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 222 may include one layer or a stack of layers, and the one or more layers may include silicon oxide, silicon dioxide, and/or a high-k dielectric material. The high-k dielectric material included in the gate dielectric layer of the transistor 222 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

Electrical signals, such as power and/or input/output (I/O) signals, may be routed to and/or from the transistors 222 of the device layer 220 through one or more metal layers 230 disposed on the device layer 220, illustrated in FIG. 2 as metal layers 230-1, 230-2, and 230-3. For example, electrically conductive features of the device layer 220 (e.g., the gate 226 and the S/D contacts 228) may be electrically coupled with the interconnect structures 232 of the metal layers 230. Although a particular number of metal layers 230 is depicted in FIG. 2, embodiments of the present disclosure include IC devices having more or fewer metal layers than depicted. The one or more metal layers 230 may form a metallization stack 240 of the IC device 200. The metal layers 230 are examples of the metal layers 130 of the IC device 100, and the metallization stack 240 is an example of the metallization stack 140 of the IC device 100.

The interconnect structures 232 may be arranged within the metal layers 230 to route electrical signals according to a wide variety of designs (in particular, the arrangement is not limited to the particular configuration of interconnect structures 232 depicted in FIG. 2). In some embodiments, the interconnect structures 232 may include conductive lines 232a and/or conductive vias 232b, formed of an electrically conductive material such as a metal. The conductive lines 232a may be arranged to route electrical signals in a direction of a plane that is substantially parallel with a surface of the substrate 210 upon which the device layer 220 is formed. For example, the conductive lines 232a may route electrical signals in a direction in and out of the page from the perspective of FIG. 2. The conductive vias 232b may be arranged to route electrical signals in a direction of a plane that is substantially perpendicular to the surface of the substrate 210 upon which the device layer 220 is formed. In some embodiments, the conductive vias 232b may electrically couple conductive lines 232a of different metal layers 230 together.

A first metal layer 230-1 (referred to as Metal 1 or “M1”) may be formed directly on the device layer 220. In some embodiments, the first metal layer 230-1 may include conductive lines 232a and/or conductive vias 232b, as shown. The conductive lines 232a of the first metal layer 230-1 may be coupled with contacts (e.g., the S/D contacts 228) of the device layer 220.

A second metal layer 230-2 (referred to as Metal 2 or “M2”) may be formed directly on the first metal layer 230-1. In some embodiments, the second metal layer 230-2 may include conductive vias 232b to couple the conductive lines 232a of the second metal layer 230-2 with the conductive lines 232a of the first metal layer 230-1. Although the conductive lines 232a and the conductive vias 232b are structurally delineated with a line within each metal layer (e.g., within the second metal layer 230-2) for the sake of clarity, the conductive lines 232a and the conductive vias 232b may be structurally and/or materially contiguous (e.g., simultaneously filled during a dual-damascene process) in some embodiments.

A third metal layer 230-3 (referred to as Metal 3 or “M3”) (and additional metal layers, as desired) may be formed in succession on the second metal layer 230-2 according to similar techniques and configurations described in connection with the second metal layer 230-2 or the first metal layer 230-1.

The metal layers 230 may include a dielectric material 234 disposed between the interconnect structures 232, as shown in FIG. 2. The dielectric material 234 may take the form of any of the embodiments of the dielectric material provided between the interconnects of the IC structures disclosed herein, for example any of the embodiments discussed herein with reference to the insulating medium of the metallization stack 140. In some embodiments, the dielectric material 234 disposed between the interconnect structures 232 in different ones of the metal layers 230 may have different compositions. In other embodiments, the composition of the dielectric material 234 in different metal layers 230 may be the same.

The IC device 200 may include a solder resist material 236 (e.g., polyimide or similar material) and one or more conductive contacts 238 (e.g., bond pads) formed on the metal layers 230. The conductive contacts 238 may be electrically coupled with the interconnect structures 232 and configured to route the electrical signals of the transistor(s) 222 to other external devices. For example, solder bonds may be formed on the one or more conductive contacts 238 to mechanically and/or electrically couple a chip including the IC device 200 with another component (e.g., a circuit board). The IC device 200 may have other alternative configurations to route the electrical signals from the metal layers 230 than depicted in other embodiments. For example, the conductive contacts 238 illustrated in FIG. 2 as bond pads may be replaced by or may further include other analogous features (e.g., posts) that route the electrical signals to external components.

Any of the metal layers 230 may include one or more fishbone capacitor structures. An example of this is shown in FIG. 2 with a first fishbone capacitor structure 250-1 in the first metal layer 230-1 and a second fishbone capacitor structure 250-2 in the second metal layer 230-2. Although a particular number of fishbone capacitor structures 250 is depicted in FIG. 2, embodiments of the present disclosure include IC devices having more or fewer fishbone capacitor structures than depicted. The fishbone capacitor structures 250 may be arranged within the metal layers 230 to serve as capacitors (e.g., decoupling capacitors) according to a wide variety of designs (in particular, the arrangement is not limited to the particular configuration of fishbone capacitor structures 250 depicted in FIG. 2). In some embodiments, a thickness of a fishbone capacitor structure 250 (i.e., a dimension measured along the z-axis of the example coordinate system shown in the present drawings) may be substantially equal to a thickness of the conductive lines 232a (also a dimension measured along the z-axis of the example coordinate system shown in the present drawings). In some embodiments, any one of the fishbone capacitor structures 250 may be horizontally aligned (e.g., be in the same plane parallel to the substrate 210) with one or more conductive lines 232a, which is illustrated in FIG. 2 with the first fishbone capacitor structure 250-1 being horizontally aligned with the conductive line 232a of the first metal layer 230-1 and with the second fishbone capacitor structure 250-2 being horizontally aligned with the conductive lines 232a of the second metal layer 230-2. This may be a result of the fishbone capacitor structures 250 being fabricated using substantially the same patterning process as that used to form the conductive lines 232a. In some embodiments, fishbone capacitor structures 250 may be fabricated as MIM capacitors formed as part of the BEOL damascene processing.

Some examples of the fishbone capacitor structures 250 are shown in FIGS. 3A and 3B, illustrating top-down views (i.e., views of x-y planes of the example coordinate system shown in the present drawings) of example fishbone capacitor structures 250, according to some embodiments of the present disclosure.

As shown in FIG. 3A, in some embodiments, a fishbone capacitor structure 250 may include a first capacitor electrode 310, a second capacitor electrode 320, and a third capacitor electrode 330, where the second capacitor electrode 320 is between the first capacitor electrode 310 and the third capacitor electrode 330. The first capacitor electrode 310 may be formed as a first line 312 with protrusions 314 on a side of the first line 312. The second capacitor electrode 320 may be formed as a second line 322 with protrusions 324 on one side of the second line 322 and protrusions 326 on the other side of the second line 322. The third capacitor electrode 330 may be formed as a third line 332 with protrusions 334 on a side of the third line 332. The protrusions described herein may also be referred to as “stubs.” Although the protrusions of various capacitor electrodes and the corresponding lines of these capacitor electrodes (e.g., the protrusions 314 and the first line 312, or the protrusions 324, 326 and the second line 322) are structurally delineated in FIG. 3A with lines for the sake of clarity, the protrusions of various capacitor electrodes and the corresponding lines of these capacitor electrodes may be structurally and/or materially contiguous (e.g., simultaneously filled during a dual-damascene process) in some embodiments. Various portions of the capacitor electrodes of the fishbone structure 250 may be formed of one or more electrically conductive materials, e.g., of one or more metals or metal alloys as described with reference to the conductive metals of the metallization stack 140.

In some embodiments, the length of the protrusions of various capacitor electrodes described herein (e.g., the protrusions 314, 324, 326, and 334), which may be a dimension measured along the y-axis of the example coordinate system shown in FIGS. 3A and 3B, may be between about 5 and 2000 nanometers, e.g., between 5 and 1000 nanometers, between 5 and 500 nanometers, or between 5 and 250 nanometers. In some embodiments, the width of the lines of various capacitor electrodes described herein (e.g., the lines 312, 322, and 332), which may also be a dimension measured along the y-axis of the example coordinate system shown in FIGS. 3A and 3B, may be between about 5 and 2000 nanometers, e.g., between 5 and 1000 nanometers, between 5 and 500 nanometers, or between 5 and 250 nanometers. In some embodiments, the width of the protrusions of various capacitor electrodes described herein (e.g., the protrusions 314, 324, 326, and 334), which may be a dimension measured along the x-axis of the example coordinate system shown in FIGS. 3A and 3B, may be between about 5 and 2000 nanometers, e.g., between 5 and 1000 nanometers, between 5 and 500 nanometers, or between 5 and 250 nanometers.

The protrusions 314 of the first capacitor electrode 310 and the protrusions 324 on one side of the second capacitor electrode 320 face one another and are interleaved with one another, as shown in FIG. 3A, thus forming a first interdigitated capacitor structure (or a first MIM capacitor) 350-1 (together with the corresponding lines 312 and 322). The protrusions 334 of the third capacitor electrode 330 and the protrusions 326 on the other side of the second capacitor electrode 320 face one another and are interleaved with one another, as also shown in FIG. 3A, thus forming a second interdigitated capacitor structure (or a first MIM capacitor) 350-2 (together with the corresponding lines 332 and 322). In some embodiments, closest portions of the first capacitor electrode 310 and portions on one side of the second capacitor electrode 320 may be separated by a distance between about 2 and 20 nanometers, e.g., between 2 and 10 nanometers, or between 2 and 7 nanometers. Closest portions of the third capacitor electrode 330 and portions on the other side of the second capacitor electrode 320 may be separated by a similar distance. An insulator material 352-1 may separate the first capacitor electrode 310 and portions on one side of the second capacitor electrode 320, thus serving as a capacitor insulator of the first interdigitated capacitor structure 350-1. Similarly, an insulator material 352-2 may separate the third capacitor electrode 330 and portions on the other side of the second capacitor electrode 320, thus serving as a capacitor insulator of the second interdigitated capacitor structure 350-2. In some embodiments, any of the insulator materials 352 may be an ILD material such as any of the materials described with reference to the ILD material of the insulating medium of the IC device 100 (e.g., the dielectric material 234 of the IC device 200). In some embodiments, any of the insulator materials 352 may be a high-k dielectric. In some embodiments, the insulator materials 352 disposed between capacitor electrodes of different ones of the interdigitated capacitor structures 350 may have different compositions. In other embodiments, the composition of the insulator material 352 disposed between capacitor electrodes of different ones of the interdigitated capacitor structures 350 may be the same. During operation, different ones of the capacitor electrodes of the fishbone capacitor structure 250 may be connected to respective terminals for connecting to a power delivery network, thus serving as independently controlled capacitor electrodes of the interdigitated capacitor structures 350.

FIG. 3A illustrates that, in some embodiments, the protrusions 324 on the first side of the second line 322 and the protrusions 326 on the second side of the second line 322 may be symmetric with respect to the second line 322. This is what makes the second capacitor electrode 320 look like a fishbone, based on which the name “fishbone capacitor structure” was created. FIG. 3A further illustrates that, in some embodiments, the protrusions 314 and the protrusions 334 may be symmetric with respect to the second line 322, facing one another.

FIG. 3B illustrates a fishbone capacitor structure 250 as described with reference to FIG. 3A, but further comprising a fourth capacitor electrode 340. The fourth capacitor electrode 340 may be formed as a fourth line 342 with protrusions 344 on a side of the fourth line 342. The third capacitor electrode 330 is between the second capacitor electrode 320 and the fourth capacitor electrode 340, so that the third line 332 is between the second line 322 and the fourth line 342, and the protrusions 344 extend towards the third line 332. In such embodiments, the third capacitor electrode 330 may further have protrusions 336 on the other side of the third line 332, so that the protrusions 334 and 336 are on different sides of the third line 332, similar to how the protrusions 324 and 326 are on different sides of the second line 322. The protrusions 344 of the fourth capacitor electrode 340 and the protrusions 336 on the second side of the third line 332 face one another and are interleaved with one another, as shown in FIG. 3B, thus forming a third interdigitated capacitor structure (or a third MIM capacitor) 350-3 (together with the corresponding lines 332 and 342). Closest portions of the fourth capacitor electrode 340 and portions on the side of the third capacitor electrode 330 facing the fourth capacitor electrode 340 may be separated by a distance similar to that described above with reference to the closest portions of the first capacitor electrode 310 and portions on one side of the second capacitor electrode 320. An insulator material 352-3 may separate the fourth capacitor electrode 340 and portions on the side of the third capacitor electrode 330 facing the fourth capacitor electrode 340, thus serving as a capacitor insulator of the third interdigitated capacitor structure 350-3. In some embodiments, the insulator material 352-3 may be a high-k dielectric.

FIG. 3B further illustrates that, in some embodiments, the protrusions 334 on the first side of the third line 332 and the protrusions 336 on the second side of the third line 332 may be symmetric with respect to the third line 332. This is what makes the third capacitor electrode 330 of this embodiment also look like a fishbone, similar to the second capacitor electrode 320. In some embodiments, a shape of the second capacitor electrode 320 may be substantially same as a shape of the third capacitor electrode 330, except that their respective protrusions may be offset so that the protrusions 326 of the second capacitor electrode 320 may interleave with the protrusions 334 of the third capacitor electrode 330. FIG. 3B further illustrates that, in some embodiments, the protrusions 326 on the second side of the second line 322 and the protrusions 344 on the side of the fourth line 342 may be symmetric with respect to the third line 332.

Inclusion of the fourth capacitor electrode 340 may advantageously increase capacitance of the fishbone capacitor structure 250, compared to the fishbone capacitor structure 250 shown in FIG. 3A. In some embodiments, fishbone capacitor structures 250 described herein may be extended to include even more capacitor electrodes, similar to how the differences between FIG. 3B and FIG. 3A were described.

Fishbone capacitor structures as described herein, e.g., fishbone capacitor structures 250 as described with reference to FIG. 2 or FIG. 3, may be included in any of the metal layers 130.

The IC structures with fishbone capacitor structures disclosed herein may be included in any suitable electronic device. FIGS. 4-6 illustrate various examples of apparatuses that may include one or more fishbone capacitor structures disclosed herein (e.g., one or more fishbone capacitor structures 250 according to any of the embodiments disclosed herein).

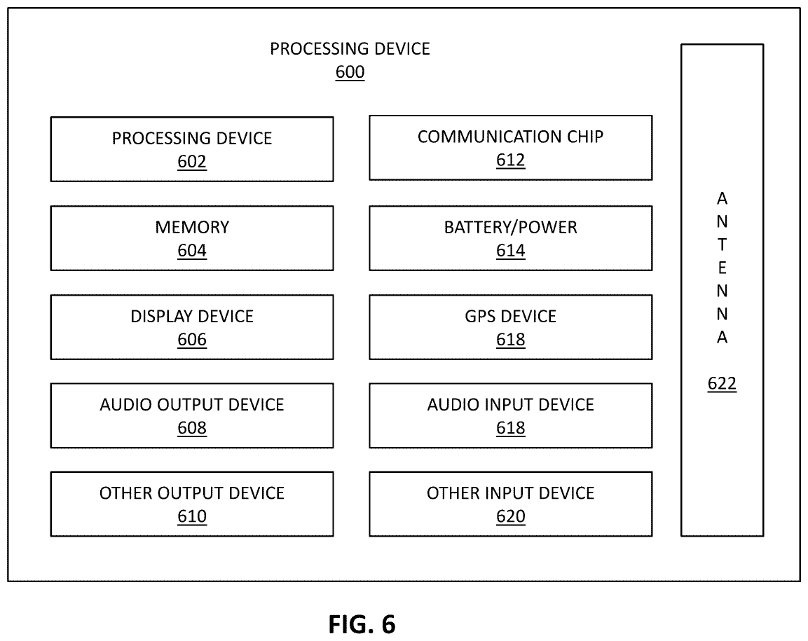

FIGS. 4A and 4B are top views of a wafer and dies that include one or more IC structures with one or more fishbone capacitor structures (e.g., one or more fishbone capacitor structures 250) in accordance with any of the embodiments disclosed herein. The wafer 400 may be composed of semiconductor material and may include one or more dies 402 having IC structures formed on a surface of the wafer 400. Each of the dies 402 may be a repeating unit of a semiconductor product that includes any suitable IC structure (e.g., the IC structure with one or more fishbone capacitor structures 250). After the fabrication of the semiconductor product is complete (e.g., after manufacture of one or more IC structures with one or more fishbone capacitor structures 250 as described herein, included in a particular IC device, e.g., in an IC device 100/200), the wafer 400 may undergo a singulation process in which each of the dies 402 is separated from one another to provide discrete “chips” of the semiconductor product. In particular, devices that include one or more IC structures with one or more fishbone capacitor structures 250 as disclosed herein may take the form of the wafer 400 (e.g., not singulated) or the form of the die 402 (e.g., singulated). The die 402 may include one or more transistors (e.g., one or more of the transistors 222 of FIG. 2, discussed below) and/or supporting circuitry to route electrical signals to the transistors, as well as any other IC components (e.g., one or more IC structures with one or more fishbone capacitor structures 250 as discussed herein). In some embodiments, the wafer 400 or the die 402 may include a memory device (e.g., a static random-access memory (SRAM) device), a logic device (e.g., an AND, OR, NAND, or NOR gate), or any other suitable circuit element. Multiple ones of these devices may be combined on a single die 402. For example, a memory array formed by multiple memory devices may be formed on a same die 402 as a processing device (e.g., the processing device 602 of FIG. 6) or other logic that is configured to store information in the memory devices or execute instructions stored in the memory array.

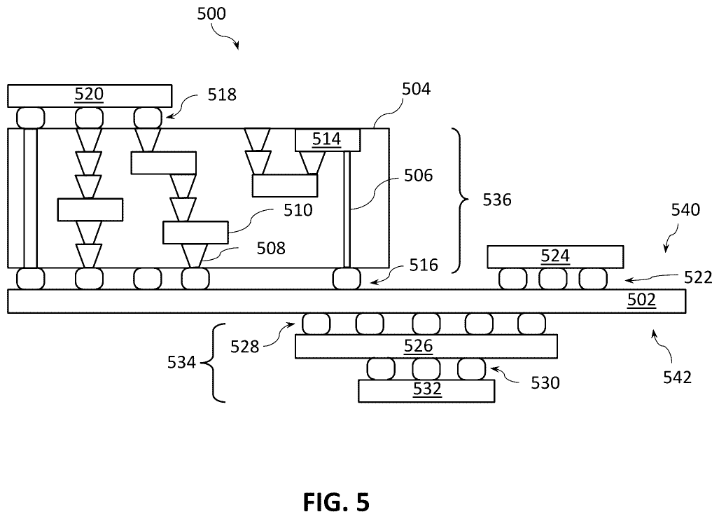

FIG. 5 is a cross-sectional side view of an IC device assembly 500 that may include components having or being associated with (e.g. being electrically connected by means of) one or more IC devices with one or more fishbone capacitor structures 250 in accordance with any of the embodiments disclosed herein. The IC device assembly 500 includes a number of components disposed on a circuit board 502 (which may be, e.g., a motherboard). The IC device assembly 500 includes components disposed on a first face 540 of the circuit board 502 and an opposing second face 542 of the circuit board 502; generally, components may be disposed on one or both faces 540 and 542. In particular, any suitable ones of the components of the IC device assembly 500 may include any of the fishbone capacitor structures 250, disclosed herein.

In some embodiments, the circuit board 502 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 502. In other embodiments, the circuit board 502 may be a non-PCB substrate.

The IC device assembly 500 illustrated in FIG. 5 includes a package-on-interposer structure 536 coupled to the first face 540 of the circuit board 502 by coupling components 516. The coupling components 516 may electrically and mechanically couple the package-on-interposer structure 536 to the circuit board 502, and may include solder balls (as shown in FIG. 5), male and female portions of a socket, an adhesive, an underfill material, and/or any other suitable electrical and/or mechanical coupling structure.

The package-on-interposer structure 536 may include an IC package 520 coupled to an interposer 504 by coupling components 518. The coupling components 518 may take any suitable form for the application, such as the forms discussed above with reference to the coupling components 516. Although a single IC package 520 is shown in FIG. 5, multiple IC packages may be coupled to the interposer 504; indeed, additional interposers may be coupled to the interposer 504. The interposer 504 may provide an intervening substrate used to bridge the circuit board 502 and the IC package 520. The IC package 520 may be or include, for example, a die (the die 402 of FIG. 4B), an IC device (e.g., the IC device 200 of FIG. 2), or any other suitable component. In some embodiments, the IC package 520 may include one or more fishbone capacitor structures 250, as described herein. Generally, the interposer 504 may spread a connection to a wider pitch or reroute a connection to a different connection. For example, the interposer 504 may couple the IC package 520 (e.g., a die) to a ball grid array (BGA) of the coupling components 516 for coupling to the circuit board 502. In the embodiment illustrated in FIG. 5, the IC package 520 and the circuit board 502 are attached to opposing sides of the interposer 504; in other embodiments, the IC package 520 and the circuit board 502 may be attached to a same side of the interposer 504. In some embodiments, three or more components may be interconnected by way of the interposer 504.

The interposer 504 may be formed of an epoxy resin, a fiberglass-reinforced epoxy resin, a ceramic material, or a polymer material such as polyimide. In some implementations, the interposer 504 may be formed of alternate rigid or flexible materials that may include the same materials described above for use in a semiconductor substrate, such as silicon, germanium, and other group III-V and group IV materials. The interposer 504 may include metal interconnects 508 and vias 510, including but not limited to TSVs 506. The interposer 504 may further include embedded devices 514, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 504. The interposer 504 may further include one or more fishbone capacitor structures 250, as described herein. The package-on-interposer structure 536 may take the form of any of the package-on-interposer structures known in the art.

The IC device assembly 500 may include an IC package 524 coupled to the first face 540 of the circuit board 502 by coupling components 522. The coupling components 522 may take the form of any of the embodiments discussed above with reference to the coupling components 516, and the IC package 524 may take the form of any of the embodiments discussed above with reference to the IC package 520.

The IC device assembly 500 illustrated in FIG. 5 includes a package-on-package structure 534 coupled to the second face 542 of the circuit board 502 by coupling components 528. The package-on-package structure 534 may include an IC package 526 and an IC package 532 coupled together by coupling components 530 such that the IC package 526 is disposed between the circuit board 502 and the IC package 532. The coupling components 528 and 530 may take the form of any of the embodiments of the coupling components 516 discussed above, and the IC packages 526 and 532 may take the form of any of the embodiments of the IC package 520 discussed above. The package-on-package structure 534 may be configured in accordance with any of the package-on-package structures known in the art.

FIG. 6 is a block diagram of an example computing device 600 that may include one or more components including one or more IC devices with one or more fishbone capacitor structures 250 in accordance with any of the embodiments disclosed herein. For example, any suitable ones of the components of the computing device 600 may include a die (e.g., the die 402 of FIG. 4B) having one or more fishbone capacitor structures 250 as described herein. Any one or more of the components of the computing device 600 may include, or be included in, an IC device 200 of FIG. 2. Any one or more of the components of the computing device 600 may include, or be included in, an IC device assembly 500 of FIG. 5.

A number of components are illustrated in FIG. 6 as included in the computing device 600, but any one or more of these components may be omitted or duplicated, as suitable for the application. In some embodiments, some or all of the components included in the computing device 600 may be attached to one or more motherboards. In some embodiments, some or all of these components are fabricated onto a single system-on-a-chip (SoC) die.

Additionally, in various embodiments, the computing device 600 may not include one or more of the components illustrated in FIG. 6, but the computing device 600 may include interface circuitry for coupling to the one or more components. For example, the computing device 600 may not include a display device 606, but may include display device interface circuitry (e.g., a connector and driver circuitry) to which a display device 606 may be coupled. In another set of examples, the computing device 600 may not include an audio input device 624 or an audio output device 608, but may include audio input or output device interface circuitry (e.g., connectors and supporting circuitry) to which an audio input device 624 or audio output device 608 may be coupled.

The computing device 600 may include a processing device 602 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 602 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 600 may include a memory 604, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 604 may include memory that shares a die with the processing device 602. This memory may be used as cache memory and may include embedded dynamic random-access memory (eDRAM) or spin transfer torque magnetic random-access memory (STT-MRAM).

In some embodiments, the computing device 600 may include a communication chip 612 (e.g., one or more communication chips). For example, the communication chip 612 may be configured for managing wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 612 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 612 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 612 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 612 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 612 may operate in accordance with other wireless protocols in other embodiments. The computing device 600 may include an antenna 622 to facilitate wireless communications and/or to receive other wireless communications (such as AM or FM radio transmissions).

In some embodiments, the communication chip 612 may manage wired communications, such as electrical, optical, or any other suitable communication protocols (e.g., the Ethernet). As noted above, the communication chip 612 may include multiple communication chips. For instance, a first communication chip 612 may be dedicated to shorter-range wireless communications such as Wi-Fi or Bluetooth, and a second communication chip 612 may be dedicated to longer-range wireless communications such as global positioning system (GPS), EDGE, GPRS, CDMA, WiMAX, LTE, EV-DO, or others. In some embodiments, a first communication chip 612 may be dedicated to wireless communications, and a second communication chip 612 may be dedicated to wired communications.

The computing device 600 may include battery/power circuitry 614. The battery/power circuitry 614 may include one or more energy storage devices (e.g., batteries or capacitors) and/or circuitry for coupling components of the computing device 600 to an energy source separate from the computing device 600 (e.g., AC line power).

The computing device 600 may include a display device 606 (or corresponding interface circuitry, as discussed above). The display device 606 may include any visual indicators, such as a heads-up display, a computer monitor, a projector, a touchscreen display, a liquid crystal display (LCD), a light-emitting diode display, or a flat panel display, for example.

The computing device 600 may include an audio output device 608 (or corresponding interface circuitry, as discussed above). The audio output device 608 may include any device that generates an audible indicator, such as speakers, headsets, or earbuds, for example.

The computing device 600 may include an audio input device 624 (or corresponding interface circuitry, as discussed above). The audio input device 624 may include any device that generates a signal representative of a sound, such as microphones, microphone arrays, or digital instruments (e.g., instruments having a musical instrument digital interface (MIDI) output).

The computing device 600 may include a GPS device 618 (or corresponding interface circuitry, as discussed above). The GPS device 618 may be in communication with a satellite-based system and may receive a location of the computing device 600, as known in the art.

The computing device 600 may include an other output device 610 (or corresponding interface circuitry, as discussed above). Examples of the other output device 610 may include an audio codec, a video codec, a printer, a wired or wireless transmitter for providing information to other devices, or an additional storage device.

The computing device 600 may include an other input device 620 (or corresponding interface circuitry, as discussed above). Examples of the other input device 620 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 600 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 600 may be any other electronic device that processes data.

### Select Examples

The following paragraphs provide various examples of the embodiments disclosed herein.

Example 1 provides an IC device that includes a die (or, more generally, a support structure), including an IC in a device layer; a metallization stack over the die; and a capacitor structure in a layer of the metallization stack. In such an IC device, the capacitor structure includes a first capacitor electrode, a second capacitor electrode, and a third capacitor electrode, the first capacitor electrode is a first line with protrusions on a side of the first line, the second capacitor electrode is a second line with protrusions on a first side of the second line and protrusions on a second side of the second line, the third capacitor electrode is a third line with protrusions on a side of the third line, the protrusions on the side of the first line and the protrusions on the first side of the second line form a first interdigitated capacitor structure, and the protrusions on the side of the third line and the protrusions on the second side of the second line form a second interdigitated capacitor structure.

Example 2 provides the IC device according to example 1, where the second capacitor electrode is between the first capacitor electrode and the third capacitor electrode.

Example 3 provides the IC device according to examples 1 or 2, where the protrusions on the side of the first line and the protrusions on the side of the third line are symmetric with respect to the second line.

Example 4 provides the IC device according to any one of the preceding examples, where the protrusions on the first side of the second line and the protrusions on the second side of the second line are symmetric with respect to the second line.

Example 5 provides the IC device according to any one of the preceding examples, further including a first insulator material between the first capacitor electrode and the second capacitor electrode, and a second insulator material between the third capacitor electrode and the second capacitor electrode.

Example 6 provides the IC device according to example 5, where at least one of the first insulator material and the second insulator material includes a high-k dielectric.

Example 7 provides the IC device according to any one of the preceding examples, where the capacitor structure further includes a fourth capacitor electrode, the fourth capacitor electrode is a fourth line with protrusions on a side of the fourth line, the third line is between the second line and the fourth line, and the protrusions on the side of the fourth line extend towards the third line.

Example 8 provides the IC device according to example 7, where the side of the third line is a first side of the third line, the third capacitor electrode further includes protrusions on a second side of the third line, and the protrusions on the side of the fourth line and the protrusions on the second side of the third line form a third interdigitated capacitor structure.

Example 9 provides the IC device according to examples 7 or 8, where the protrusions on the second side of the second line and the protrusions on the side of the fourth line are symmetric with respect to the third line.

Example 10 provides the IC device according to any one of examples 7-9, where the protrusions on the first side of the third line and the protrusions on the second side of the third line are symmetric with respect to the third line.

Example 11 provides the IC device according to any one of examples 7-10, where a shape of the second capacitor electrode is substantially same as a shape of the third capacitor electrode.

Example 12 provides the IC device according to any one of examples 7-11, further including a further insulator material between the third capacitor electrode and the fourth capacitor electrode.

Example 13 provides the IC device according to example 12, where the further insulator material includes a high-k dielectric.

Example 14 provides an IC device that includes a support (e.g., a substrate, a die, a wafer, or a chip); a plurality of layers of an insulator material above the support; and a capacitor structure in one of the plurality of layers, the capacitor structure including a first capacitor electrode, a second capacitor electrode, and a third capacitor electrode, where the second capacitor electrode is between the first capacitor electrode and the third capacitor electrode and has a fishbone structure, the first capacitor electrode includes stubs interlacing with stubs of a first side of the fishbone structure, and the third capacitor electrode includes stubs interlacing with stubs of a second side of the fishbone structure.

Example 15 provides the IC device according to example 14, where at least a portion of the third capacitor electrode is symmetric with the first capacitor electrode.

Example 16 provides the IC device according to examples 14 or 15, where the stubs of the first side of the fishbone structure are symmetric with the stubs of the second side of the fishbone structure.

Example 17 provides the IC device according to any one of examples 14-16, further including a conductive line in the one of the plurality of layers, where a thickness of the capacitor structure is substantially same as a thickness of the conductive line.

Example 18 provides the IC device according to any one of examples 14-17, further including a fourth capacitor electrode, where the third capacitor electrode is between the second capacitor electrode and the fourth capacitor electrode and further includes stubs interlacing with stubs of the fourth capacitor electrode.

Example 19 provides an IC package that includes an IC device according to any one of the preceding examples; and a further component, coupled to the IC device.

Example 20 provides the IC package according to example 19, where the further component is or includes one of a package substrate, an interposer, or a further IC die.

In various further examples of the IC package according to examples 19 or 20, the further component may be coupled to the IC die via one or more first-level interconnects, where the one or more first-level interconnects may include one or more solder bumps, solder posts, or bond wires.

In further examples of the IC package according to any of the preceding examples, the IC die includes, or is a part of, at least one of a memory device, a computing device, a wearable device, a handheld electronic device, and a wireless communications device.

Example 21 provides an electronic device that includes a carrier substrate; and one or more of the IC device according to any one of the preceding examples and the IC package according to any one of the preceding examples, coupled to the carrier substrate.

Example 22 provides the electronic device according to example 21, where the carrier substrate is a motherboard.

Example 23 provides the electronic device according to example 21, where the carrier substrate is a PCB.

Example 24 provides the electronic device according to any one of examples 21-23, where the electronic device is a wearable electronic device (e.g., a smart watch) or handheld electronic device (e.g., a mobile phone).

Example 25 provides the electronic device according to any one of examples 21-24, where the electronic device further includes one or more communication chips and an antenna.

Example 26 provides the electronic device according to any one of examples 21-25, where the electronic device is a memory device.

Example 27 provides the electronic device according to any one of examples 21-25, where the electronic device is one of an RF transceiver, a switch, a power amplifier, a low-noise amplifier, a filter, a filter bank, a duplexer, an upconverter, or a downconverter of an RF communications device, e.g., of an RF transceiver.

Example 28 provides the electronic device according to any one of examples 21-25, where the electronic device is a computing device.

Example 29 provides the electronic device according to any one of examples 21-28, where the electronic device is included in a base station of a wireless communication system.

Example 30 provides the electronic device according to any one of examples 21-28, where the electronic device is included in a user equipment device (i.e., a mobile device) of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a die, comprising an IC;
a metallization stack over the IC; and
a capacitor structure in a layer of the metallization stack, the capacitor structure comprising a first capacitor electrode, a second capacitor electrode, and a third capacitor electrode,
wherein the first capacitor electrode is a first line with protrusions on a side of the first line, the second capacitor electrode is a second line with protrusions on a first side of the second line and protrusions on a second side of the second line, the third capacitor electrode is a third line with protrusions on a side of the third line, the protrusions on the side of the first line and the protrusions on the first side of the second line form a first interdigitated capacitor structure, and the protrusions on the side of the third line and the protrusions on the second side of the second line form a second interdigitated capacitor structure.

2. The IC device according to claim 1, wherein the second capacitor electrode is between the first capacitor electrode and the third capacitor electrode.

3. The IC device according to claim 1, wherein the protrusions on the side of the first line and the protrusions on the side of the third line are symmetric with respect to the second line.

4. The IC device according to claim 1, wherein the protrusions on the first side of the second line and the protrusions on the second side of the second line are symmetric with respect to the second line.

5. The IC device according to claim 1, further comprising a first insulator material between the first capacitor electrode and the second capacitor electrode, and a second insulator material between the third capacitor electrode and the second capacitor electrode.

6. The IC device according to claim 5, wherein at least one of the first insulator material and the second insulator material includes a high-k dielectric.

7. The IC device according to claim 1, wherein the capacitor structure further includes a fourth capacitor electrode, the fourth capacitor electrode is a fourth line with protrusions on a side of the fourth line, the third line is between the second line and the fourth line, and the protrusions on the side of the fourth line extend towards the third line.

8. The IC device according to claim 7, wherein the side of the third line is a first side of the third line, the third capacitor electrode further includes protrusions on a second side of the third line, and the protrusions on the side of the fourth line and the protrusions on the second side of the third line form a third interdigitated capacitor structure.

9. The IC device according to claim 7, wherein the protrusions on the second side of the second line and the protrusions on the side of the fourth line are symmetric with respect to the third line.

10. The IC device according to claim 7, wherein the protrusions on the first side of the third line and the protrusions on the second side of the third line are symmetric with respect to the third line.

11. The IC device according to claim 7, wherein a shape of the second capacitor electrode is substantially same as a shape of the third capacitor electrode.

12. The IC device according to claim 7, further comprising a further insulator material between the third capacitor electrode and the fourth capacitor electrode.

13. The IC device according to claim 12, wherein the further insulator material includes a high-k dielectric.

14. An integrated circuit (IC) device, comprising:
a support structure;
a plurality of layers of an insulator material above the support structure; and
a capacitor structure in one of the plurality of layers, the capacitor structure comprising a first capacitor electrode, a second capacitor electrode, and a third capacitor electrode,
wherein the second capacitor electrode is between the first capacitor electrode and the third capacitor electrode and has a fishbone structure, the first capacitor electrode includes stubs interlacing with stubs of a first side of the fishbone structure, and the third capacitor electrode includes stubs interlacing with stubs of a second side of the fishbone structure.

15. The IC device according to claim 14, wherein at least a portion of the third capacitor electrode is symmetric with the first capacitor electrode.

16. The IC device according to claim 14, wherein the stubs of the first side of the fishbone structure are symmetric with the stubs of the second side of the fishbone structure.

17. The IC device according to claim 14, further comprising a conductive line in the one of the plurality of layers, wherein a thickness of the capacitor structure is substantially same as a thickness of the conductive line.

18. The IC device according to claim 14, further comprising a fourth capacitor electrode, wherein the third capacitor electrode is between the second capacitor electrode and the fourth capacitor electrode and further includes stubs interlacing with stubs of the fourth capacitor electrode.

19. An integrated circuit (IC) package, comprising:
an IC die, comprising an IC device; and
a further component, coupled to the IC die,
wherein the IC device includes a substrate and a capacitor structure over the substrate, the capacitor structure comprising a first capacitor electrode, a second capacitor electrode, and a third capacitor electrode,
wherein the first capacitor electrode is a first line with stubs on a side of the first line, the second capacitor electrode is a second line with stubs on a first side of the second line and stubs on a second side of the second line, the third capacitor electrode is a third line with stubs on a side of the third line, the stubs on the side of the first line and the stubs on the first side of the second line form a first interdigitated capacitor structure, and the stubs on the side of the third line and the stubs on the second side of the second line form a second interdigitated capacitor structure.

20. The IC package according to claim 19, wherein the further component is one of a package substrate, an interposer, or a further IC die.
